(19) United States
(12) Patent Application Publication
(10) Pub. No.: US 2024/0044710 A1
(43) Pub. Date: Feb. 8, 2024

(54) DETERIORATION EVALUATION METHOD OF LINE SENSOR, SPECTRUM MEASUREMENT DEVICE, AND COMPUTER READABLE MEDIUM

(71) Applicant: GIGAPHOTON INC., Tochigi (JP)

(72) Inventors: Natsuhiko KOUNO, Oyama-shi (JP); Masato MORIYA, Oyama-shi (JP)

(73) Assignee: GIGAPHOTON INC., Tochigi (JP)

(21) Appl. No.: 18/482,411

(22) Filed: Oct. 6, 2023

Related U.S. Application Data
(63) Continuation of application No. PCT/JP2021/017881, filed on May 11, 2021.

(51) Int. Cl. G01J 3/45; G01J 3/18

(52) U.S. Cl. CPC G01J 3/45; G01J 3/18

(57) ABSTRACT

A deterioration evaluation method of a line sensor includes detecting an interference fringe of pulse laser light using the line sensor; calculating, based on a signal value obtained from each of a plurality of sensor channels included in a sensor channel range being at least a part of the line sensor in accordance with light intensity of the interference fringe, an evaluation value which is an index of deterioration for each of the sensor channels or each group of the sensor channels, and storing the evaluation value in a storage device; and determining a deterioration state of the line sensor based on the evaluation value.

### CROSS-REFERENCE TO RELATED APPLICATIONS

The present application claims the benefit of International Application No. PCT/JP2021/017881, filed on May 11, 2021, the entire contents of which are hereby incorporated by reference.

### BACKGROUND

### 1. Technical Field

The present disclosure relates to a deterioration evaluation method of a line sensor, a spectrum measurement device, and a computer readable medium.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 pm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be narrowed to the extent that the chromatic aberration can be ignored. For this purpose, there is a case in which a line narrowing module (LNM) including a line narrowing element (etalon, grating, and the like) is provided in a laser resonator of the gas laser device to narrow a spectral line width. In the following, a gas laser device with a narrowed spectral line width is referred to as a line narrowing gas laser device.

### LIST OF DOCUMENTS

### Patent Documents

Patent Document 1: Japanese Patent No. 4629910
Patent Document 2: UK Patent No. 2374267

### SUMMARY

A deterioration evaluation method of a line sensor according to an aspect of the present disclosure includes detecting an interference fringe of pulse laser light using the line sensor; calculating, based on a signal value obtained from each of a plurality of sensor channels included in a sensor channel range being at least a part of the line sensor in accordance with light intensity of the interference fringe, an evaluation value which is an index of deterioration for each of the sensor channels or each group of the sensor channels, and storing the evaluation value in a storage device; and determining a deterioration state of the line sensor based on the evaluation value.

A spectrum measurement device according to another aspect of the present disclosure includes an optical system configured to generate an interference fringe by causing pulse laser light to be incident thereon, a line sensor configured to detect the interference fringe, and a processor configured to process information obtained from the line sensor. Here, the processor is configured to calculate, based on a signal value obtained from each of a plurality of sensor channels included in a sensor channel range being at least a part of the line sensor in accordance with light intensity of the interference fringe, an evaluation value which is an index of deterioration for each of the sensor channels or each group of the sensor channels, store the evaluation value in a storage device, and determine a deterioration state of the line sensor based on the evaluation value.

A computer readable medium according to another aspect of the present disclosure, being a non-transitory computer readable medium, in which a program is recorded, the program causing a processor to execute a process of acquiring a signal output from a line sensor which detects an interference fringe of pulse laser light, a process of calculating, based on a signal value obtained from each of a plurality of sensor channels included in a sensor channel range being at least a part of the line sensor in accordance with light intensity of the interference fringe, an evaluation value which is an index of deterioration for each of the sensor channels or each group of the sensor channels and storing the evaluation value in a storage device, and a process of determining a deterioration state of the line sensor based on the evaluation value.

### BRIEF DESCRIPTION OF THE DRAWINGS

Embodiments of the present disclosure will be described below merely as examples with reference to the accompanying drawings.

FIG. 1 is a schematic view showing the schematic configuration of an etalon spectrometer.

FIG. 2 shows an example of a case in which interference fringes are detected using a line sensor.

FIG. 3 is a graph showing an example of the light intensity distribution of an interference fringe, and shows a calculation method for obtaining the square of the radius of the interference fringe.

FIG. 4 is a graph showing an example of the light intensity distribution of the interference fringes detected by the line sensor, and shows a calculation method for obtaining the square of the radius of the inner first fringe.

FIG. 5 is a graph showing an example of the light intensity distribution of the interference fringes detected by the line sensor, and shows a calculation method for obtaining the square of the radius of the inner second fringe.

FIG. 6 is a graph showing an example of the light intensity distribution of the interference fringes detected by the line sensor, and shows a specific example of values of calculated fringe orders.

FIG. 7 is a graph showing an example of a spectrum measurement waveform obtained from a fringe having a fringe order value of 1.21.

FIG. 8 schematically shows the configuration of a laser device according to a first comparative example.

FIG. 9 schematically shows the configuration of the laser device according to a second comparative example.

FIG. 10 is a graph showing an example in which a free-run spectrum is detected using the line sensor without deterioration.

FIG. 11 is a graph showing an example in which a free-run spectrum is detected using the line sensor including a deteriorated sensor channel.

FIG. 12 schematically shows the configuration of the laser device according to a first embodiment.

FIG. 13 is graph showing an example of a fringe waveform of a first pulse obtained from the line sensor.

FIG. 14 is a table showing an example of count values for each sensor channel when counting is performed only for the sensor channel exceeding a light amount threshold in the fringe waveform of the first pulse in FIG. 13.

FIG. 15 is graph showing an example of the fringe waveform of a second pulse.

FIG. 16 is a table showing an example of count values for each sensor channel at the end of the second pulse.

FIG. 17 is a graph showing an example of the fringe waveform detected by the line sensor.

FIG. 18 is a graph showing an example of an average value of background noise of the line sensor calculated in advance.

FIG. 19 is a graph showing an example of the fringe waveform of light amount values obtained by subtracting the average value of the background noise in FIG. 18 from the fringe waveform in FIG. 17.

FIG. 20 is a graph showing an example of the count values when 50 billion pulses is reached.

FIG. 21 is graph showing an example of the fringe waveform of the first pulse in a second embodiment.

FIG. 22 is a table showing an example of light amount integration values at the end of the first pulse for sensor channels of sensor channel numbers in a range from 101 to 110.

FIG. 23 is graph showing an example of the fringe waveform of the second pulse.

FIG. 24 is a table showing an example of light amounts of the second pulse for the sensor channels of the sensor channel numbers in the range from 101 to 110.

FIG. 25 is a table showing an example of the light amount integration values at the end of the second pulse for the sensor channels of the sensor channel numbers in the range from 101 to 110.

FIG. 26 is a graph showing an example of the light amount integration values when 50 billion pulses is reached.

FIG. 27 is graph showing an example of the fringe waveform of the first pulse in a third embodiment.

FIG. 28 is a table showing an example of the count values of the value of MavEx counted for each group of a fringe order.

FIG. 29 is a graph showing an example of the count values when 50 billion pulses is reached.

FIG. 30 is a graph showing an example of the fringe waveform according to a fourth embodiment, and shows an example in which the sensor channels in a range corresponding to MavEx of 0.5 to 1.5 are counted.

FIG. 31 is a graph showing an example of the count values when 50 billion pulses is reached.

FIG. 32 is a graph showing an example of the light amount integration values when 50 billion pulses is reached.

FIG. 33 is a flowchart showing an example of a process of counting the number of times the fringe light amount exceeds the light amount threshold for each sensor channel to determine the deterioration state.

FIG. 34 is a flowchart showing an example of a process of integrating the fringe light amount for each sensor channel to determine the deterioration state of the line sensor.

FIG. 35 is a graph showing an example of a sensor deterioration characteristic of the line sensor.

FIG. 36 is a graph showing an example of a look-up table (LUT1) reflecting the sensor deterioration characteristic applied to a fifth embodiment.

FIG. 37 is a graph obtained by converting the vertical axis of the graph of FIG. 26 into an irradiation energy integration amount.

FIG. 38 is a graph showing a sensitivity estimation amount for each sensor channel obtained by converting the graph of FIG. 37 using LUT1.

FIG. 39 is a graph showing an example of a look-up table (LUT2) reflecting the sensor deterioration characteristic and correction for sensitivity decrease applied to a sixth embodiment.

FIG. 40 is a graph showing the sensitivity estimation amount for each sensor channel obtained by converting the graph of FIG. 37 using LUT2.

FIG. 41 schematically shows a configuration example of an exposure apparatus.

### DESCRIPTION OF EMBODIMENTS

### Contents

1. Description of terms and technology
1.1 Principle of etalon spectrometer
1.2 Calculation of measurement wavelength
1.3 Description of fringe order MavEx
   2. Overview of laser device according to first comparative example
2.1 Configuration
2.2 Operation
   3. Overview of laser device according to second comparative example
3.1 Configuration
3.2 Operation

### 4. Problem

5. First embodiment
5.1 Configuration
5.2 Operation
5.3 Effect
   6. Second embodiment
6.1 Configuration
6.2 Operation
6.3 Effect
   7. Third embodiment
7.1 Configuration
7.2 Operation
7.3 Effect
   8. Fourth embodiment
8.1 Configuration
8.2 Operation
8.3 Effect
   9. Fifth embodiment
9.1 Configuration
9.2 Operation
9.3 Effect
   10. Sixth embodiment
10.1 Configuration
10.2 Operation
10.3 Effect
   11. Other examples of laser device
   12. Computer readable medium in which program is recorded
   13. Electronic device manufacturing method

### 14. Others

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. DESCRIPTION OF TERMS AND TECHNOLOGY

### 1.1 Principle of Etalon Spectrometer

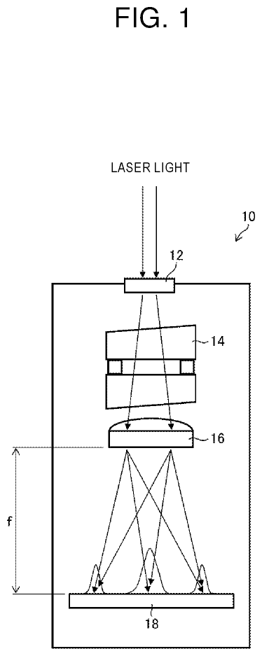

FIG. 1 is a schematic view showing the schematic configuration of an etalon spectrometer 10. As shown in FIG. 1, the etalon spectrometer 10 includes a diffusion element 12, a Fabry-Perot (FP) etalon 14, a light concentrating lens 16, and a line sensor 18. The line sensor 18 may be a linear image sensor or a photodiode array.

The laser light is incident on the diffusion element 12. The diffusion element 12 scatters the incident laser light. The scattered light enters the FP etalon 14. The laser light transmitted through the FP etalon 14 is incident on the light concentrating lens 16. The laser light is transmitted through the light concentrating lens 16 and generates interference fringes on the focal plane. The line sensor 18 is arranged at the focal plane of the light concentrating lens 16 having a focal length f. The transmitted light concentrated by the light concentrating lens 16 causes interference fringes to be generated at the position of the line sensor 18. The line sensor 18 detects the light intensity of the interference fringes generated by the FP etalon 14.

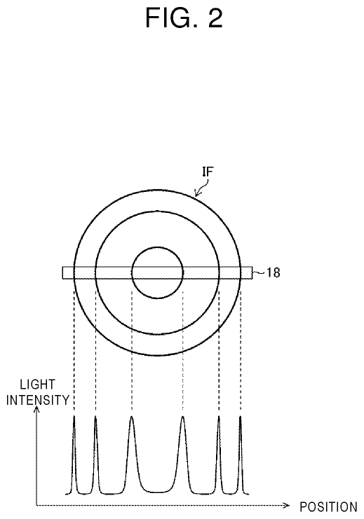

FIG. 2 shows an example of a case in which the light intensity of the interference fringes IF is detected using the line sensor 18. A plan view showing the positional relationship between the interference fringes IF and the line sensor 18 is shown in the upper part of FIG. 2, and an example of a detection signal obtained from the line sensor 18 is shown in the lower part of FIG. 2. The horizontal axis represents a position, and may be, for example, a sensor channel number indicating a position of each light receiving element (sensor channel) of the line sensor 18. The vertical axis represents the light intensity of the detected interference fringes IF, and may be, for example, a digital signal value of the detection signal output from each sensor channel, or a value obtained by normalizing with the maximum value in the intensity distribution being “1.”

As shown in FIG. 2, high light intensity is detected at each of positions where the interference fringes IF hit on the detection surface (light receiving surface) of the line sensor 18. In the interference fringes IF shown in FIG. 2, concentric rings indicated by solid lines represent peak positions (bright parts) of the light intensity. As shown in the lower part of FIG. 2, a waveform indicating the light intensity distribution of the interference fringes IF is referred to as a fringe waveform. In the following description, the center of the interference fringes IF is referred to as a “fringe center.” Each bright part of the interference fringes IF is referred to as a “fringe”, and the fringes are distinguished from each other by being assigned with numbers from the inner side such that the fringe closest to the fringe center is the first, the fringe on the next outer side is the second, and the like.

### 1.2 Calculation of Measurement Wavelength

In general, the interference fringes of an etalon are expressed by the following Expression (1).

$$\begin{matrix}[ Expression 1 ] & \\ λ = \frac{2 nd}{m} cos θ = \frac{2 nd}{m} ( 1 - \frac{{{r}_{m}}^{2}}{2 {f}^{2}} ) & ( 1 )\end{matrix}$$

Here, λ is the wavelength of laser light, n is the refractive index of an air gap, d is the distance between mirrors, m is an integer which is not 0, θ is the incident angle of the laser light, and rₘ is the interference fringe radius.

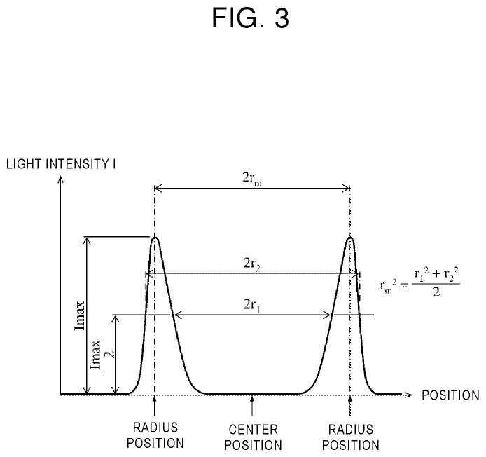

As shown in Expression (1), the square of the interference fringe radius rₘ is proportional to the wavelength λ of the laser light. Therefore, the spectral line width (spectral profile) and the center wavelength of the entire laser light can be detected from the detected interference fringes. The spectral line width and the center wavelength may be obtained from the detected interference fringes by an information processing device (not shown) or may be calculated by a wavelength control unit (e.g., a wavelength control unit 60 of FIG. 3).

FIG. 3 is a graph showing an example of the light intensity distribution of an interference fringe detected by the line sensor 18, where the horizontal axis represents the position on the detection surface and the vertical axis represents light intensity I. The square of the interference fringe radius rₘ may be calculated from the average value of the square of an inner radius r₁ and the square of an outer radius r₂ at the inner and outer positions of half value of the interference fringe, respectively. That is, the square of the interference fringe radius rₘ may be obtained from the following Expression (2).

rₘ²=(r₁²+r₂²)/2 (2)

The half value of the interference fringe indicates a half value (50% intensity) Imax/2 of peak intensity Imax at the fringe peak in the waveform indicating the intensity distribution.

### 1.3 Description of Fringe Order MavEx

As described above, the wavelength λ of the laser light is proportional to the square of the interference fringe radius rₘ. Using this relationship, a fringe order is defined as an index representing the relative position of the fringe peak in the wavelength space. The fringe order is calculated as follows.

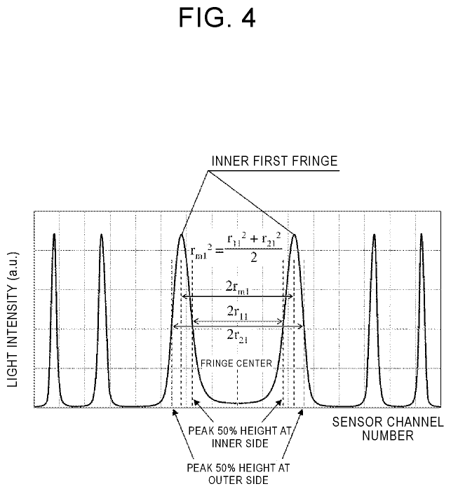

First, in a similar manner as in FIG. 3, as shown in FIG. 4, the sensor channel positions (on both inner and outer sides) corresponding to 50% of height of each of the two intensity peaks of the inner first fringe are calculated. The sensor channel positions corresponding to the 50% height of the intensity peak is calculated by linear interpolation of the real channels at two points before and after. Calculation of r₁ and r₂₁ is performed, where r₁₁ is one half of the distance between the two inner positions at 50% height of the fringe and r₂₁ is one half of the distance between the two outer positions at 50% height of the fringe, and a radius rₘ₁ is calculated from the following Expression (3).

rₘ₁²=(r₁₁²+r₂₁²)/2 (3)

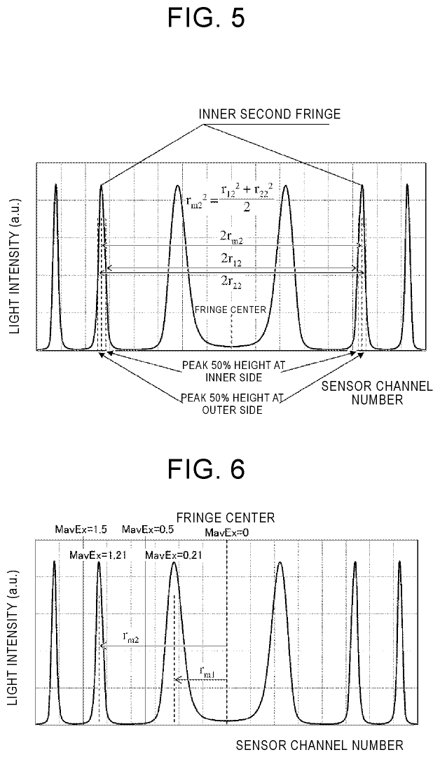

Similarly, as shown in FIG. 5, from the sensor channel positions (on both inner and outer sides) corresponding to the 50% height of the two intensity peaks of the second inner fringe, r₁₂ and r₂₂ are calculated, where r₁₂ is one half of the distance between the inner positions at 50% height of the fringe and r₂₂ is one half of the distance between the outer positions at 50% height of the fringe, and a radius rₘ₂ is calculated from the following Expression (4).

rₘ₂²=(r₁₂²+r₂₂²)/2 (4)

Here, MavEx is defined by the following Expression (5), where the fringe order at a position with a distance from the fringe center being r is taken as MavEx.

MavEx=r²/(rₘ₂²−rₘ₁²) (5)

As shown in FIG. 6, assuming that MavEx at r=rₘ₁ is 0.21, MavEx at r=rₘ₂ is 1.21. In this way, the difference in fringe orders between adjacent fringes is always 1.

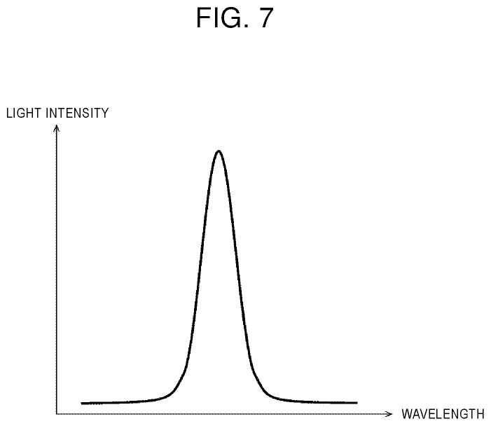

For example, in the left half from the fringe center, the fringe with MavEx being 1.21 is the only fringe with MavEx being between 0.5 and 1.5. This property of the fringe order makes it possible to calculate the center wavelength and the spectral line width by selecting a fringe in a specific range. FIG. 7 shows an example of a spectrum measurement waveform obtained from the fringe of MavEx=1.21. In FIG. 7, the horizontal axis represents the wavelength and the vertical axis represents the light intensity.

### 2. OVERVIEW OF LASER DEVICE ACCORDING TO FIRST COMPARATIVE EXAMPLE

### 2.1 Configuration

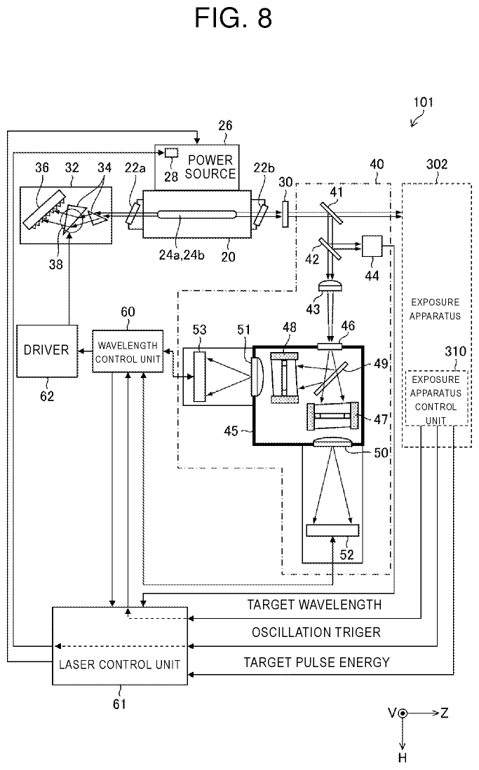

FIG. 8 is a diagram schematically showing the configuration of a laser device 101 according to a first comparative example. The comparative example of the present disclosure is an example recognized by the applicant as known only by the applicant, and is not a publicly known example admitted by the applicant. As shown in FIG. 8, the laser device 101 is a line narrowing gas laser device including a chamber 20, a power source 26, an output coupling mirror 30, a line narrowing module 32, a monitor module 40, the wavelength control unit 60, a laser control unit 61, and a driver 62.

The output coupling mirror 30 and the line narrowing module 32 configure a laser resonator. The chamber 20 is arranged on the optical path of the laser resonator. The line narrowing module 32 includes a plurality (e.g., two) of prisms 34, a grating 36, and a rotation stage 38.

The prism 34 is arranged to function as a beam expander. The grating 36 is arranged in the Littrow arrangement so that the incident angle and the diffraction angle coincide with each other. The prism 34 is installed on the rotation stage 38, and is arranged such that the incident angle of on the grating 36 changes by the rotation of the prism 34 with the rotation stage 38.

The chamber 20 includes windows 22a, 22b and a pair of electrodes 24a, 24b. The chamber 20 contains a laser gas. The laser gas may include, for example, an Ar gas or a Kr gas as a rare gas, an F₂ gas as a halogen gas, and an Ne gas as a buffer gas.

The electrodes 24a, 24b are arranged in the chamber 20 so as to face each other in a direction (V direction) perpendicular to the paper surface of FIG. 8 and so that the longitudinal direction of the electrodes 24a, 24b coincides with the direction of the optical path of the laser resonator. The electrodes 24a, 24b are connected to the power source 26.

The power source 26 includes a switch 28, and applies a high voltage between the electrodes 24a, 24b in the chamber 20 when the switch 28 is turned on.

The windows 22a, 22b are arranged such that the laser light amplified by discharge excitation between the electrodes 24a, 24b passes therethrough.

The output coupling mirror 30 is coated with a film that reflects a part of the laser light and transmits the other part.

The monitor module 40 includes a beam splitter 41, a beam splitter 42, a light concentrating lens 43, a pulse energy monitor 44, a sealed chamber 45, a line sensor 52, and a line sensor 53.

The beam splitter 41 is arranged, on the optical path of the laser light output from the output coupling mirror 30, such that the laser light reflected by the beam splitter 41 is incident on the beam splitter 42. The laser light transmitted through the beam splitter 41 is output from the laser device 101. An exposure apparatus 302 is arranged such that the laser light output from the laser device 101 enters the exposure apparatus 302.

The beam splitter 42 is arranged, on the optical path of the laser light reflected by the beam splitter 41, such that the laser light reflected by the beam splitter 42 enters the pulse energy monitor 44. The pulse energy monitor 44 may be a photodiode, a photoelectric tube, or a pyro-element.

The light concentrating lens 43 is arranged such that the laser light transmitted through the beam splitter 42 is incident thereon.

The sealed chamber 45 includes a diffusion plate 46, a fine etalon 47, a coarse etalon 48, a beam splitter 49, a light concentrating lens 50, and a light concentrating lens 51.

The diffusion plate 46 is arranged in the vicinity of the concentration position of the light concentrating lens 43. The diffusion plate 46 is an optical element made of synthetic quartz having one surface flat and the other surface processed into a ground glass shape. The diffusion plate 46 is sealed to the sealed chamber 45 with an O-ring (not shown).

The fine etalon 47 is arranged such that the laser light transmitted through the diffusion plate 46 is transmitted through the beam splitter 49 and enters the fine etalon 47. The beam splitter 49 is arranged, on the optical path between the diffusion plate 46 and the fine etalon 47, such that the laser light partially reflected by the beam splitter 49 enters the coarse etalon 48. Each of the fine etalon 47 and the coarse etalon 48 may be an air gap etalon in which two mirrors each coated with a partial reflection film are joined via a spacer.

A free spectral range FSRf of the fine etalon 47 and a free spectral range FSRc of the coarse etalon 48 satisfy the following Expression (6).

FSRf<FSRc (6)

A free spectral range FSR is expressed by the following Expression (7).

FSR=λ²/(2nd) (7)

Generally, when the finesse of the etalon is F, the resolution R is expressed by R=FSR/F. When the finesse F is fixed, the resolution R becomes large as FSR becomes small. However, when FSR becomes small, the interference fringes become substantially the same in a case where the wavelength changes by the amount of the FSR, and thus it cannot be distinguished by measurement using one etalon having small FSR.

Therefore, when the wavelength is changed by about 400 pm and measured with high accuracy as in the case of an excimer laser, the wavelength can be measured with high accuracy by measuring the interference fringes of the fine etalon 47 and the coarse etalon 48 by the line sensor 52 and the line sensor 53, respectively. FSRf of the fine etalon 47 may be, for example, 10 pm, and FSRc of the coarse etalon 48 may be, for example, 400 pm.

The light concentrating lens 50 is arranged on the optical path of the laser light transmitted through the fine etalon 47, and is sealed with an O-ring (not shown) to the sealed chamber 45. The light concentrating lens 51 is arranged on the optical path of the laser light transmitted through the coarse etalon 48, and is sealed with an O-ring (not shown) to the sealed chamber 45. The focal length of the light concentrating lens 51 is shorter than the focal length of the light concentrating lens 50.

The line sensor 52 and the line sensor 53 are arranged at the focal plane positions of the light concentrating lens 50 and the light concentrating lens 51, respectively. Each of the line sensor 52 and the line sensor 53 has a plurality of light receiving elements arranged one-dimensionally, and outputs a detection signal corresponding to the light intensity of the received interference fringes. Each of the line sensor 52 and the line sensor 53 includes a signal processing circuit including an A/D converter that converts a detection signal corresponding to the received light amount into digital data. The light amount detected by the respective light receiving elements of the line sensors 52, 53 is output respectively from the line sensors 52, 53 as a signal value represented by, for example, a 12 bit digital value.

The light receiving element corresponds to a “pixel”, and each of the plurality of light receiving elements is referred to as a sensor channel. The position of the interference fringes on the detection plane can be represented by a sensor channel number indicating the position of the sensor channel.

The interference fringes of the etalon are expressed by Expression (8) from Expression (1).

mλ=2nd·cos θ (8)

The wavelength control unit 60 is configured to be capable of communicating with the line sensor 52, the line sensor 53, the laser control unit 61, and the driver 62. The wavelength control unit 60 and the laser control unit 61 are realized by using a processor. The processor of the present disclosure is a processing device including a storage device in which a control program is stored and a central processing unit (CPU) that executes the control program. The processor is specifically configured or programmed to perform various processes included in the present disclosure. The processor functioning as the wavelength control unit 60 and the processor functioning as the laser control unit 61 may be separately provided, or both functions may be realized by one processor.

The laser control unit 61 is configured to be capable of communicating with the power source 26, the switch 28, the pulse energy monitor 44, and the exposure apparatus control unit 310 of the exposure apparatus 302. The driver 62 is configured to be capable of communicating with the rotation stage 38.

### 2.2 Operation

The laser control unit 61 reads data of a target pulse energy Et and a target wavelength λt from the exposure apparatus control unit 310. The laser control unit 61 transmits a charge voltage V to the power source 26 and the target wavelength λt to the wavelength control unit 60 so that the pulse energy of the pulse laser light becomes the target pulse energy Et and the oscillation wavelength becomes the target wavelength λt. The laser control unit 61 turns on the switch 28 based on an oscillation trigger transmitted from the exposure apparatus control unit 310.

When the switch 28 is turned on, a high voltage is applied between the electrodes 24a, 24b, and discharge occurs to excite the laser gas. When the laser gas is excited, laser oscillation occurs in the laser resonator configured by the line narrowing module 32 and the output coupling mirror 30, and line narrowed pulse laser light is output from the output coupling mirror 30.

The pulse laser light output from the output coupling mirror 30 and sampled by the beam splitter 41 is incident on the beam splitter 42. The reflection light of the beam splitter 42 enters the pulse energy monitor 44, and the transmission light of the beam splitter 42 is incident on the diffusion plate 46 of the sealed chamber 45.

The laser control unit 61 controls the charge voltage V of the power source 26 based on the detection result of the pulse energy monitor 44 so that the pulse energy of the pulse laser light becomes the target pulse energy Et.

On the other hand, the wavelength control unit 60 measures the light intensity distribution of the interference fringes generated by the coarse etalon 48 and the fine etalon 47 for each pulse using the line sensor 53 and the line sensor 52, and reads the data thereof. The wavelength control unit 60 calculates the measurement wavelength λ of the pulse laser light for each pulse from the data of the light intensity distribution of the interference fringes read for each pulse. The calculation of the measurement wavelength λ may be performed from data obtained by performing integration or averaging of a plurality of pulses instead of each pulse. The wavelength control unit 60 controls the rotation stage 38 of the prism 34 via the driver 62 based on the measurement wavelength λ so that the oscillation wavelength of the pulse laser light becomes the target wavelength λt.

As described above, the pulse energy and the oscillation wavelength of the laser device 101 are stabilized to the target pulse energy Et and the target wavelength λt given by the exposure apparatus 302. Here, since the sealed chamber 45 is sealed, the difference in the refractive index n of the air gap in Expression (1) between the coarse etalon 48 and the fine etalon 47 is suppressed to be small, and the error of the wavelength measurement due to the drift of the coarse etalon 48 and the fine etalon 47 is reduced.

### 3. OVERVIEW OF LASER DEVICE ACCORDING TO SECOND COMPARATIVE EXAMPLE

### 3.1 Configuration

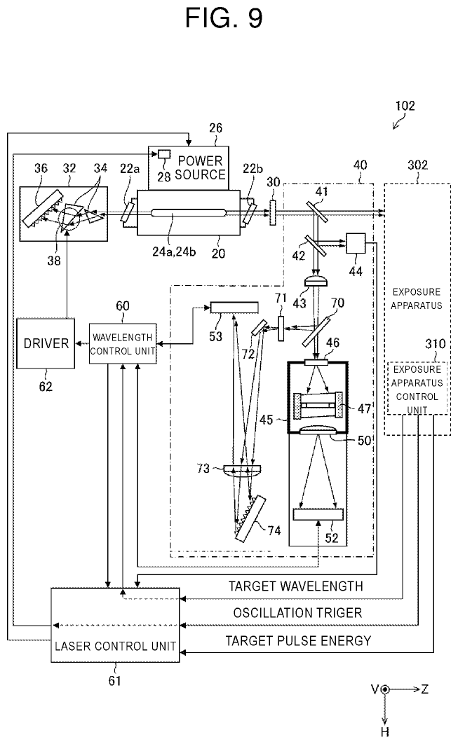

FIG. 9 is a diagram schematically showing the configuration of a laser device 102 according to a second comparative example. The configuration shown in FIG. 9 will be described in terms of differences from the configuration shown in FIG. 8. The laser device 102 shown in FIG. 9 includes a grating spectrometer instead of the coarse etalon 48 shown in FIG. 8. By measuring a wavelength range corresponding to FSRc using the grating spectrometer, and performing the measurement of the interference fringes simultaneously with the fine etalon 47, it is possible to measure the wavelength in a wide range with high accuracy in cooperation. The laser device 102 includes a beam splitter 70, an aperture 71, a mirror 72, a collimating lens 73, and a coarse grating 74.

The beam splitter 70 is arranged on the optical path of the laser light having passed through the light concentrating lens 43. The aperture 71 is arranged in the vicinity of the concentration position of the light concentrating lens 43 such that the laser light reflected by the beam splitter 70 is incident thereon.

The mirror 72 is arranged such that the laser light having passed through the aperture 71 is incident thereon. The collimating lens 73 is arranged such that the laser light reflected by the mirror 72 is incident thereon. The coarse grating 74 is arranged so as to reflect the laser light incident from the collimating lens 73 toward the collimating lens 73.

The line sensor 53 is arranged such that the laser light reflected by the coarse grating 74 and having passed through the collimating lens 73 enters. Other configurations may be similar to those in FIG. 8.

### 3.2 Operation

The pulse laser light output from the output coupling mirror 30 and sampled by the beam splitter 41 is incident on the beam splitter 42. The transmission light from the beam splitter 42 is transmitted through the light concentrating lens 43 and is incident on the beam splitter 70.

The reflection light of the beam splitter 70 is incident on the aperture 71. The transmission light of the beam splitter 70 is incident on the diffusion plate 46 of the sealed chamber 45.

The pulse laser light having passed through the aperture 71 is reflected by the mirror 72, is collimated by the collimating lens 73, and is incident on the coarse grating 74. The pulse laser light diffracted by the coarse grating 74 is transmitted through the collimating lens 73 and generates interference fringes at the position of the light receiving surface of the line sensor 53.

As described above, according to the laser device 102, the wavelength range corresponding to the free spectral range FSRc of the coarse etalon 48 can be measured by the grating spectrometer. Therefore, similarly to the laser device 101, the laser device 102 shown in FIG. 9 can measure the wavelength in a wide range with high accuracy in cooperation by performing measurement for each pulse by the line sensor 53 and the line sensor 52.

### 4. PROBLEM

The line sensors 52, 53 of the monitor module 40 each have a lifetime. The line sensors 52, 53 deteriorate due to long term use, and the sensor sensitivity thereof is decreased.

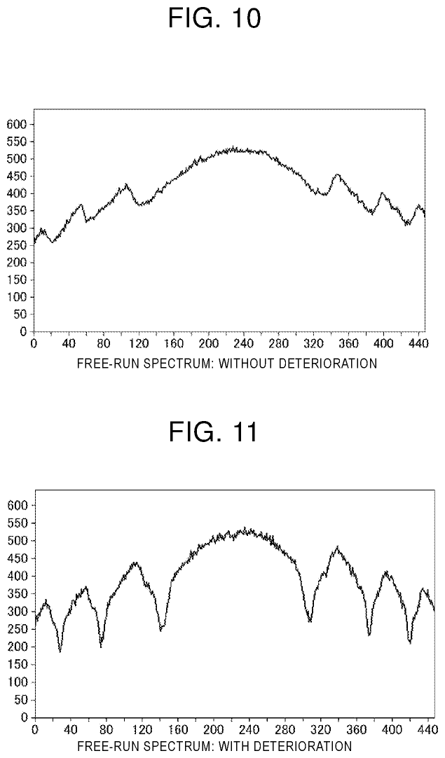

FIG. 10 is a graph showing an example in which a free-run spectrum is detected using the line sensor 52 in a state without deterioration. FIG. 11 is a graph showing an example in which a free-run spectrum is detected using the line sensor 52 including a sensor channel in a deteriorated state. In FIGS. 10 and 11, the horizontal axis represents the sensor channel number of the line sensor 52, and the vertical axis represents the measurement value of the light intensity.

As can be seen from the comparison between FIGS. 10 and 11, the sensor channel in a deteriorated state has a decreased sensor sensitivity, and it becomes difficult to obtain an accurate measurement value. Such a phenomenon is not limited to the line sensor 52, and the same applies to other line sensors such as the line sensor 53. The deterioration degree of each sensor channel (the degree of decrease in sensor sensitivity) is related to the cumulative amount of irradiation energy of the pulse laser light radiated to each sensor channel. The cumulative amount of the irradiation energy of the pulse laser light radiated to each sensor channel may be referred to as the received light integration amount of each sensor channel.

In the laser devices 101, 102 shown in the first comparative example and the second comparative example, the monitor module 40 used in excess of a number of shots (shot limit) determined in advance assuming this deterioration was replaced uniformly.

However, it has been found that, depending on the usage conditions of the monitor module 40 and individual differences between the line sensors 52, 53, even when used in excess of the shot limit, the linearity error is within an allowable range and many monitor modules 40 are sufficiently usable.

Therefore, it is economically desirable to evaluate the deterioration of the uniformity of the sensor sensitivity of the line sensors 52, 53 or the measurement linearity error of the etalon measurement instrument in a field of a semiconductor manufacturing factory or the like, and replace only the monitor module 40 having a problem. Accordingly, there has been a demand for a method of individually evaluating the deterioration state of the line sensors 52, 53 to determine whether or not replacement is necessary.

### 5. FIRST EMBODIMENT

### 5.1 Configuration

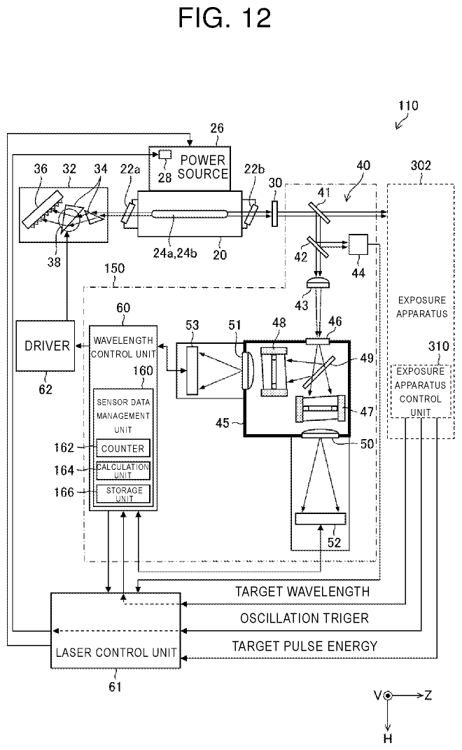

FIG. 12 schematically shows the configuration of a laser device 110 including a spectrum measurement device 150 according to a first embodiment. The configuration shown in FIG. 12 will be described in terms of differences from the configuration shown in FIG. 8. In the laser device 110, a sensor data management unit 160 is added to the wavelength control unit 60 of FIG. 8. The sensor data management unit 160 is also realized by using a processor, similarly to the wavelength control unit 60 and the laser control unit 61. The sensor data management unit 160 includes a counter 162, a calculation unit 164, and a storage unit 166. The spectrum measurement device 150 includes the monitor module 40 and the wavelength control unit 60. Other configurations may be similar to those in FIG. 8. Here, the sensor data management unit 160 may be added to the wavelength control unit 60 of FIG. 9.

### 5.2 Operation

Operation of the sensor data management unit 160 will be described. Here, the deterioration evaluation method is exemplified using the line sensor 52 as an example, but the deterioration evaluation method for other line sensors such as the line sensor 53 is also similar.

[Step 1A] The sensor data management unit 160 integrates the number of times the light amount of the fringe pattern exceeds a threshold for each sensor channel of the line sensor 52, and stores the count value for each sensor channel in the storage unit 166 in the sensor data management unit 160. For example, when the digital output standard of each sensor channel of the line sensor 52 is 12 bits, the signal value output from the sensor channel indicating the light amount measurement value may be a value of 0 to 4095. In this case, since the SN ratio is increased to such an extent that the signal value is not saturated, the signal value is often adjusted so that the fringe peak value becomes 2000 to 3000.

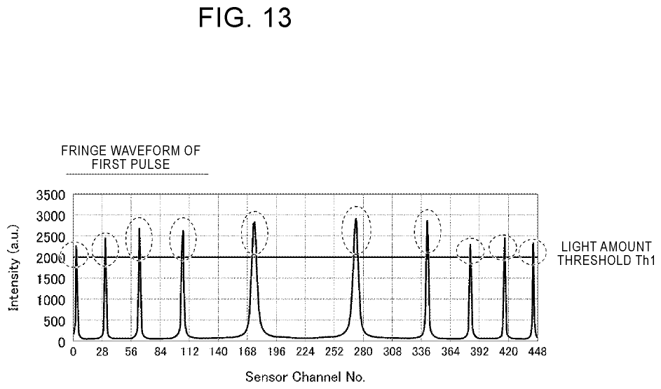

FIG. 13 shows an example of the fringe waveform of the first pulse obtained under the condition that the fringe peak value is 2000 to 3000. Shown in the following is an example in which a light amount threshold Th1 is set to 2000, and only when the light amount threshold Th1 is exceeded, the number of times thereof is counted for each sensor channel. The light amount threshold Th1 set to 2000 is an example of the “first threshold” in the present disclosure. FIG. 13 is an example of the fringe waveform detected using the line sensor 52 having 448 sensor channels. In FIG. 13, the fringe peaks exceeding the light amount threshold Th1 are surrounded by broken line circles.

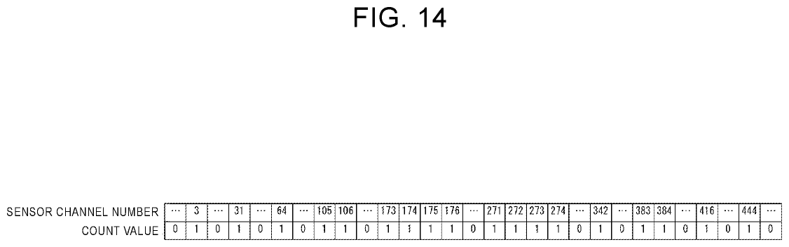

The table shown in FIG. 14 shows an example of count values for each sensor channel when counting is performed only for the sensor channels exceeding the light amount threshold Th1 (=2000) in the fringe waveform of a first pulse. Here, “1” is counted for the sensor channels in which the light amount exceeding the light amount threshold Th1 is detected.

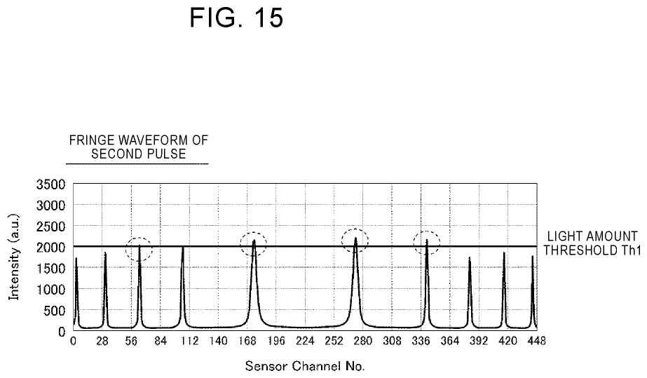

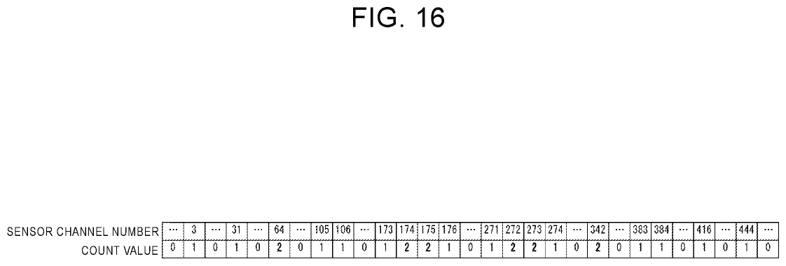

Subsequently, with respect to the fringe waveform of a second pulse, similarly, counting is performed only for the sensor channels exceeding the light amount threshold Th1 and addition is performed to the previously recorded (previous) count value. FIG. 15 is an example of the fringe waveform of the second pulse detected using the line sensor 52 having the same 448 sensor channels. In FIG. 15, the sensor channel numbers each detecting the light amount exceeding the light amount threshold Th1 are 64, 174, 175, 272, 273, and 342. In this case, as shown in FIG. 16, at the end of the second pulse, “1” is added to the previous count values (in FIG. 14) for these sensor channel numbers, and the count values are updated.

In this way, the sensor data management unit 160 integrates the number of times the light amount threshold Th1 is exceeded for each sensor channel. The count value is used as an index (evaluation index of local deterioration) for quantitatively evaluating local deterioration due to accumulation of light reception of each sensor channel. It can be evaluated that the deterioration degree becomes high as the count value becomes large. The count value is an example of the “evaluation value” in the present disclosure.

The integration for each sensor channel exceeding the light amount threshold Th1 may be performed not for all pulses but for every certain number of pulses. For example, the integration for each sensor channel exceeding the light amount threshold Th1 may be performed at a frequency of 1 pulse every 10 pulses.

Further, the integration for sensor channels exceeding the light amount threshold Th1 may be performed not for the fringe waveform obtained by 1 pulse but for the fringe waveform obtained by integration of a certain number of pulses. For example, the integration for the sensor channels exceeding the light amount threshold Th1 may be performed on each fringe waveform obtained by integrating irradiation of 10 pulses.

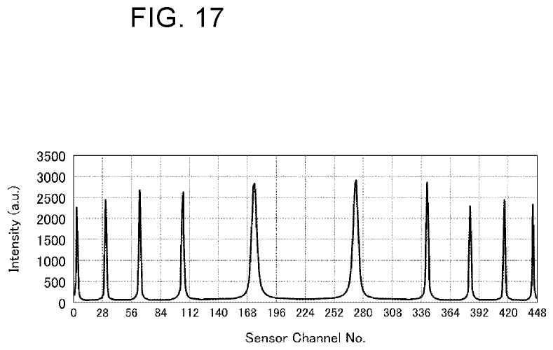

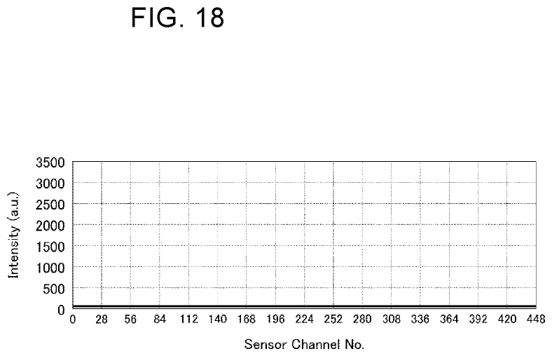

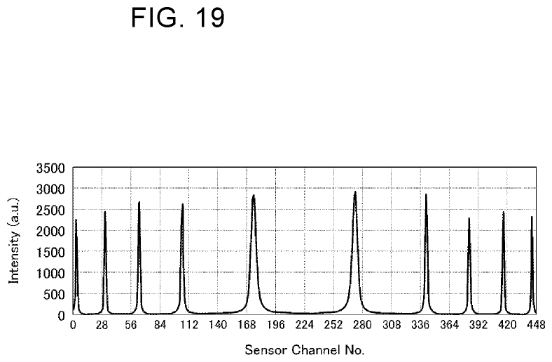

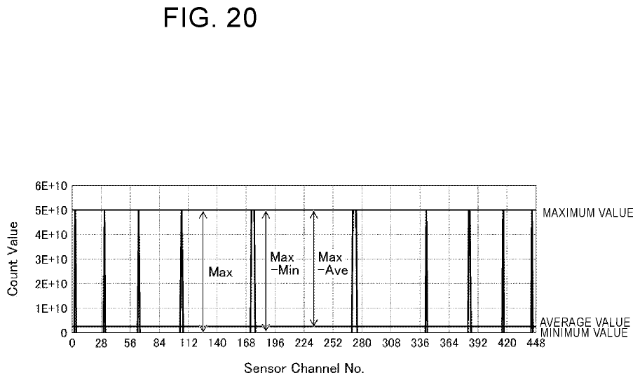

The determination of whether or not the light amount threshold Th1 has been exceeded is not limited to the process in which the light amount measurement values detected by the respective sensor channels are directly compared with the light amount threshold Th1 as shown in FIG. 17. For example, as shown in FIG. 18, the average value of the background noise of the line sensor 52 may be obtained in advance, and the determination of whether or not the light amount threshold Th1 has been exceeded may be performed with respect to the fringe waveform (see FIG. 19) after subtracting the average value of the background noise (see FIG. 18) from the light amount measurement value (FIG. 17) detected by each sensor channel. The average value of the background noise is an example of the “third constant” in the present disclosure.

[Step 2A] The calculation unit 164 of the sensor data management unit 160 calculates, each time, the maximum value of the count values of the respective sensor channels counted by the process in step 1A. Alternatively, the maximum value, the minimum value, and the average value are calculated each time, and the difference between the maximum value and the minimum value or the difference between the maximum value and the average value is calculated each time. Here, “each time” means each time data of the fringe light amount is read from the line sensor 52. In a case in which data is read once per pulse, this means that data is read once each time in units of a pulse, and in a case in which data is read once from the line sensor 52 per the integration of a certain number of pulses, this means that data is read each time in units of a certain number of pulses.

[Step 3A] The sensor data management unit 160 sets a threshold Th2 for the maximum value of the count values obtained by the process in step 2A, and determines that the line sensor 52 is in a deteriorated state in which an accurate fringe pattern cannot be obtained when the maximum value exceeds the threshold Th2. For example, when the threshold Th2 for the maximum value of the count values is set to 50,000,000,000 (50 billion) and the maximum value of the count values of the sensor channels recorded in the sensor data management unit 160 as shown in FIG. 20 exceeds 50 billion, the line sensor 52 is determined to be in a deteriorated state in which an accurate fringe pattern cannot be obtained.

The threshold determination method applied to the maximum value may be applied to the value of the difference between the maximum value and the minimum value or the value of the difference between the maximum value and the average value. The threshold Th2 set to 50 billion is an example of the “second threshold” in the present disclosure.

[Step 4A] When the value counted in step 2A or the threshold Th2 for determination causes an overflow, the sensor data management unit 160 may use a value obtained by dividing the counted value or the threshold Th2 by a certain value. For example, the threshold Th2 exemplified in step 3A may be a value obtained by dividing 50 billion by 1,000,000, that is, 50,000. In this case, the count value recorded for each sensor channel of the line sensor 52 may be integrated by similarly dividing the value by 1,000,000, and the threshold determination may be performed by calculating the maximum value, the difference between the maximum value and the minimum value, or the difference between the maximum value and the average value. The divisor 1,000,000 is an example of the “first constant” in the present disclosure.

[Step 5A] The count value of each sensor channel and the result of the threshold determination may be displayed on a user interface that monitors the operation state of the laser device 110. For example, the processor functioning as the sensor data management unit 160 may be connected to a display device (not shown), and the count values and the result of the threshold determination may be displayed on the display device.

[Step 6A] When the value used for the threshold determination (the count value in the first embodiment) exceeds the threshold Th2, a warning may be displayed on the user interface in step 5A, or the occurrence of the warning may be recorded in a log. The sensor data management unit 160 may execute at least one of a process of displaying the determination result on the display device, a process of recording the determination result in the log, and a process of performing notification based on the determination result.

<Others> Although the above operation is described using a fringe pattern formed by the etalon spectroscope, similar operation may be performed not only for an etalon spectroscope but also for a grating spectroscope. Here, although an example in which an etalon spectrometer is used will be described for second to sixth embodiments described below, similar operation as in the second to sixth embodiment may be performed for the grating spectrometer. The etalon spectrometer and the grating spectrometer are examples of the “optical system” in the present disclosure.

### 5.3 Effect

According to the first embodiment, since a decrease in sensitivity of a specific sensor channel of the line sensor 52, 53 can be detected, it is possible to replace the line sensor 52 or the line sensor 53 that has deteriorated or the monitor module 40 while the influence is small. Thus, it is possible to maintain a state in which the wavelength and the spectral line width can be appropriately measured.

Further, according to the first embodiment, since the replacement can be performed after detecting that the line sensor 52, 53 is actually in a deteriorated state, it is economically advantageous as compared with a case in which the replacement is uniformly performed based on the shot limit.

### 6. SECOND EMBODIMENT

### 6.1 Configuration

The configuration of a second embodiment may be similar to that of the first embodiment shown in FIG. 12.

### 6.2 Operation

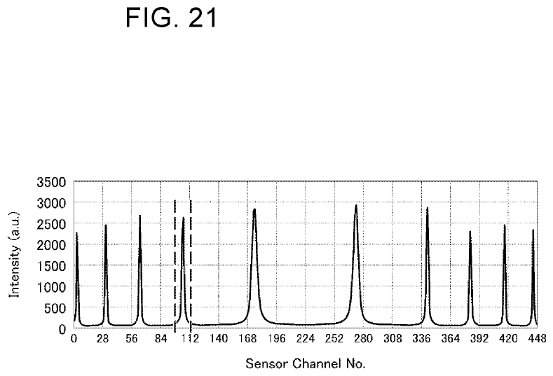

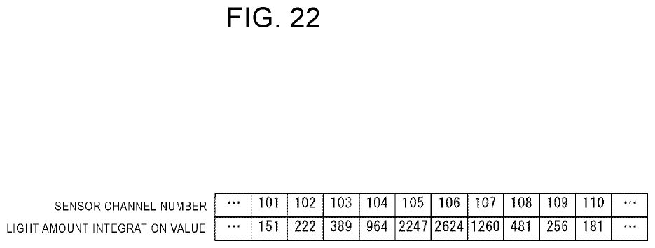

Differences from the first embodiment will be described. In the first embodiment, the number of times the signal value of each sensor channel (a value corresponding to the light amount) output in accordance with the light intensity of the interference fringe exceeds the light amount threshold Th1 is counted for each sensor channel, but in the second embodiment, the signal value of each sensor channel is integrated for each sensor channel, and the deterioration state is evaluated using the light amount integration values. The sensor data management unit 160 of the second embodiment operates as follows.

[Step 1B] The sensor data management unit 160 integrates the light amount of the fringe pattern for each sensor channel of the line sensor 52, and stores the light amount integration value for each sensor channel in the storage unit 166 in the sensor data management unit 160. For example, FIG. 21 represents the fringe waveform of the first pulse detected on the line sensor 52 having 448 sensor channels, and the light amount integration values of the sensor channels of the channel numbers in a range from 101 to 110 at the end of the first pulse are as shown in FIG. 22.

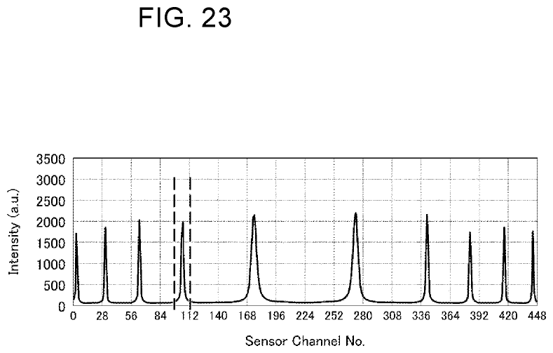

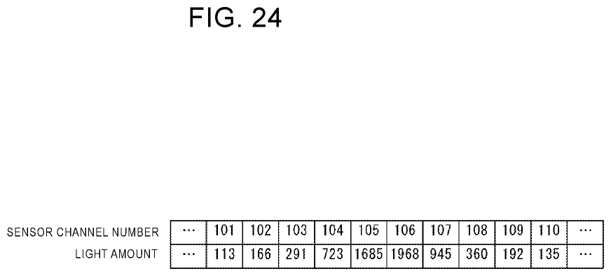

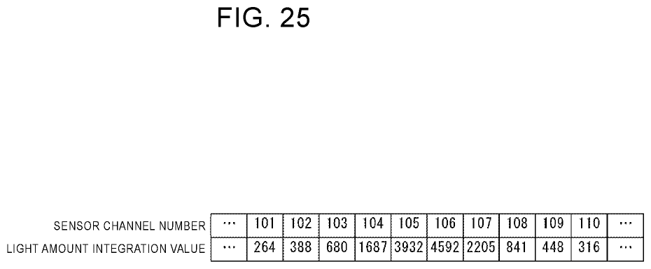

Subsequently, when the fringe waveform of the second pulse detected on the same line sensor 52 having 448 channels is obtained as a graph shown in FIG. 23, the light amounts of the second pulse of the 101st to 110th sensor channels are as shown in FIG. 24. Here, the sensor data management unit 160 stores the light amount integration values in which the light amounts of two pulses being the first pulse and the second pulse are integrated, and at the end of the second pulse, the light amount integration values in the 101st to 110th sensor channels are as shown in FIG. 25. In this way, the integration value of the detected fringe light amounts is managed by the sensor data management unit 160 for each sensor channel. The integration light amount value is an example of the “evaluation value” in the present disclosure.

The light amount integration may be performed not for all pulses but for every certain number of pulses. For example, the light amount integration for each sensor channel may be performed at a frequency of 1 pulse every 10 pulses.

Further, the light amount integration may be performed not for the fringe waveform obtained by 1 pulse but for the fringe waveform obtained by integration of a certain number of pulses. For example, the light amount integration for each sensor channel may be performed on each fringe waveform obtained by integrating 10 pulses of irradiation.

Further, the light amount integration may be performed on the fringe waveform after subtracting the average value of the background noise calculated in advance.

[Step 2B] The calculation unit 164 of the sensor data management unit 160 calculates, each time, the maximum value of the light amount integration values of the respective sensor channels integrated by the process in step 1B. Alternatively, the maximum value, the minimum value, and the average value of the light amount integration value of each sensor channel are calculated each time, and the difference between the maximum value and the minimum value or the difference between the maximum value and the average value is calculated each time.

[Step 3B] The sensor data management unit 160 sets a threshold Th3 for the maximum value of the light amount integration values obtained by the process in step 2B, and determines that the line sensor 52 cannot obtain an accurate fringe pattern when the maximum value of the light amount integration value exceeds the threshold Th3.

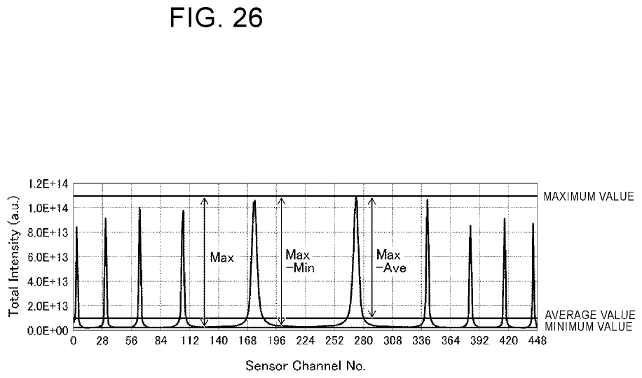

FIG. 26 is a graph showing an example of the light amount integration values of the sensor channels when 50 billion pulses is reached. For example, when the threshold Th3 of the light amount integration value is set to 100,000,000,000,000 (100 trillion) and the maximum value of the light amount integration values of the sensor channels recorded in the sensor data management unit 160 as shown in FIG. 26 exceeds 100 trillion, the line sensor 52 is determined not to be capable of obtaining an accurate fringe pattern.

The threshold determination method applied to the maximum value may be applied to the difference between the maximum value and the minimum value or the difference between the maximum value and the average value. The threshold Th3 set to 100 trillion is an example of the “second threshold” in the present disclosure.

[Step 4B] When the light amount integration value of step 2B or the threshold Th3 for determination causes an overflow in step 3B, a value obtained by dividing the light amount integration value or the threshold Th3 by a certain constant value may be used. For example, the threshold Th3 for the determination of the light amount integration value in step 2B may be a value obtained by dividing 100 trillion by 1,000,000,000, that is, 100,000. Further, the light amount integration value recorded for each sensor channel of the line sensor 52 may be recorded by similarly dividing the value by 1,000,000,000, and the threshold determination may be performed by calculating the maximum value, the difference between the maximum value and the minimum value, or the difference between the maximum value and the average value. The divisor 1,000,000,000 is an example of the “second constant” in the present disclosure.

[Step 5B] The light amount integration value of each sensor channel and the result of the threshold determination may be displayed on the user interface that monitors the operation state of the laser device 110.

[Step 6B] When the value used for the threshold determination (the light amount integration value in the second embodiment) exceeds the threshold Th3, the sensor data management unit 160 may execute at least one of a process of displaying a warning on the user interface, a process of recording an occurrence of the warning in the log, and a process of performing notification based on the determination result.

### 6.3 Effect

According to the second embodiment, the deterioration state of each sensor channel can be grasped more accurately than in the first embodiment.

### 7. THIRD EMBODIMENT

### 7.1 Configuration

The configuration of a third embodiment may be similar to that of the first embodiment shown in FIG. 12.

### 7.2 Operation

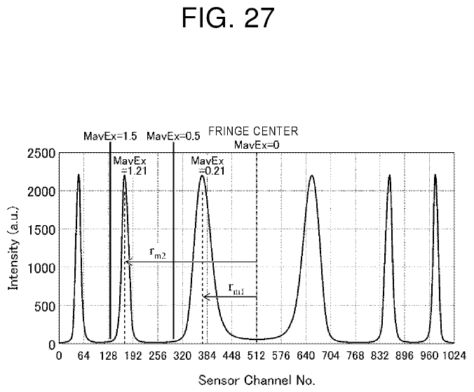

Differences from the first embodiment will be described. In the third embodiment, the target range is limited by using the fringe order MavEx, and the target range is grouped into a plurality of sections (groups) and counting is performed for each group. The sensor data management unit 160 of the third embodiment operates as follows.

[Step 1C] The sensor data management unit 160 of the third embodiment performs similar determination as in the first embodiment by counting for each group. FIG. 27 is a graph showing an example of the fringe waveform detected on the line sensor 52 having 1024 sensor channels. For example, as shown in FIG. 27, when a fringe having the value of MavEx between 0.5 and 1.5 is selected in the range of the left half from the fringe center and the center wavelength or the spectral line width is calculated, the range of MavEx to be counted (target range) may be only 0.5 to 1.5.

At this time, for example, the target range of MavEx is grouped for each range (section) of “0.1” such that the value of MavEx is grouped into 0.5 to 0.6, 0.6 to 0.7, . . . , 1.3 to 1.4, and 1.4 to 1.5, and counting is performed for each group in accordance with the value of MavEx of the fringe. Each group grouped by the range of “0.1” is an example of the “fringe order group” in the present disclosure. The grouping section of the target range of MavEx may be a value other than “0.1.”

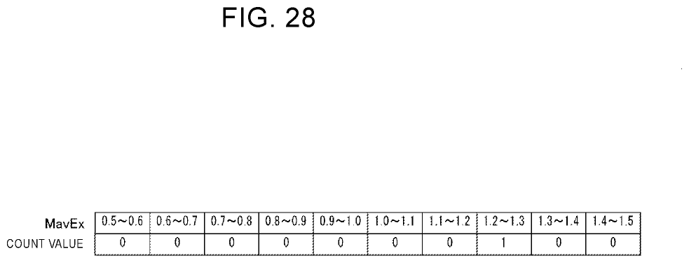

In the case of the example shown in FIG. 27, MavEx of the fringe in the range of 0.5 to 1.5 is 1.21, and in this case, “1” is counted for the group of “1.2 to 1.3” as shown in FIG. 28. When MavEx of the fringe of the next pulse is also in the range of “1.2 to 1.3”, the count value of the group “1.2 to 1.3” of MavEx becomes “2.”

When the center wavelength is calculated from the fringe, the calculation may be performed by using not only the fringe on one side such as the left half but also the fringe on both the left and right sides. Further, when the spectral line width is calculated from the fringe, the calculation may be performed using the fringe on the right side instead of the left side.

Counting for each fringe order may be performed not for all pulses but for every certain number of pulses. For example, counting may be performed for each fringe order at a frequency of 1 pulse every 10 pulses.

Further, counting for each fringe order may be performed not for the fringe waveform obtained by 1 pulse but for the fringe waveform obtained by integration of a certain number of pulses. For example, counting for each fringe order may be performed on each fringe waveform obtained by integrating 10 pulses.

Further, counting for each fringe order may be performed on the fringe waveform after subtracting the average value of the background noise calculated in advance.

[Step 2C] The calculation unit 164 of the sensor data management unit 160 calculates, each time, the maximum value of the count values of the respective groups of MavEx counted by the process in step 1C. Alternatively, the maximum value, the minimum value, and the average value are calculated each time for the count value of each group, and the difference between the maximum value and the minimum value or the difference between the maximum value and the average value is calculated each time.

[Step 3C] The sensor data management unit 160 sets a threshold Th4 for the maximum value of the count values obtained by the process in step 2C, and determines that the line sensor cannot obtain an accurate fringe pattern when the value exceeds the threshold Th4. The threshold Th4 is an example of the “second threshold” in the present disclosure.

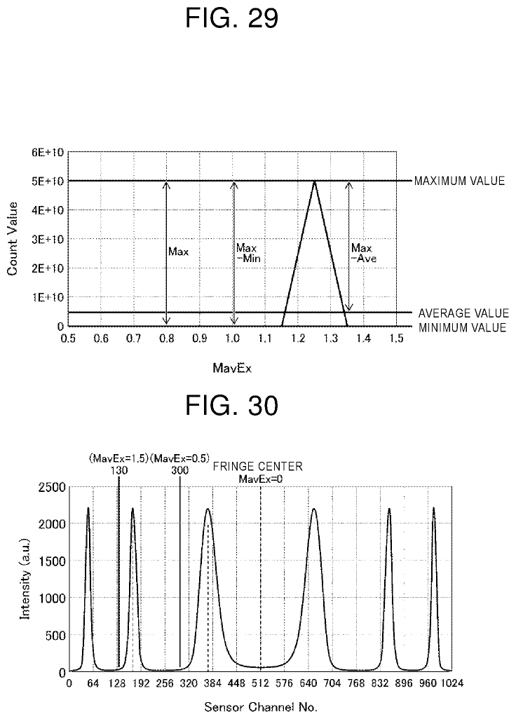

FIG. 29 is a graph showing an example of the count values for each group when 50 billion pulses is reached. For example, when the threshold Th4 for the count value is set to 50,000,000,000 (50 billion) and the maximum value of the count values of the groups of MavEx recorded in the sensor data management unit 160 as shown in FIG. 29 exceeds 50 billion, the line sensor 52 is determined not to be capable of obtaining an accurate fringe pattern.

The threshold determination method may be performed on the difference between the maximum value and the minimum value, or the difference between the maximum value and the average value.

[Step 4C] When the value counted in step 2C or the threshold Th4 causes an overflow, a value obtained by dividing the counted value or the threshold Th4 by a certain value may be used. For example, the threshold Th4 may be a value obtained by dividing 50 billion by 1,000,000, that is, 50,000. The count value recorded for each group of the sensor channels of the line sensor 52 may be integrated by similarly dividing the value by 1,000,000, and the threshold determination may be performed by calculating the maximum value, the difference between the maximum value and the minimum value, or the difference between the maximum value and the average value.

[Step 5C] The count value of each group and the result of the threshold determination may be displayed on the user interface that monitors the operation state of the laser device 110.

[Step 6C] When the value used for the threshold determination (the count value in the third embodiment) exceeds the threshold Th4, the sensor data management unit 160 may execute at least one of a process of displaying a warning on the user interface, a process of recording an occurrence of the warning in the log, and a process of performing notification based on the determination result.

The range of the value of MavEx may be associated with the range of sensor channel numbers, and grouping of the value of MavEx by “0.1” may correspond to grouping of sensor channels. The count value of the value of MavEx calculated for each group of MavEx is used as an index for quantitatively evaluating the local deterioration of the sensor channel range (group) corresponding to each group. The count value is an example of the “evaluation value” in the present disclosure.

### 7.3 Effect

According to the third embodiment, the deterioration state of the line sensor 52, 53 can be grasped more simply than in the first and second embodiments.

### 8. FOURTH EMBODIMENT

### 8.1 Configuration

The configuration of a fourth embodiment may be similar to that of the first embodiment shown in FIG. 12.

### 8.2 Operation

In the fourth embodiment, similar determination as in the first or second embodiment is performed for the sensor channels corresponding to the range of MavEx in the third embodiment.

For example, in the example shown in FIG. 30, the sensor channels in the range corresponding to MavEx of 0.5 to 1.5 in the left half range from the fringe center are the 130th to 300th sensor channels.

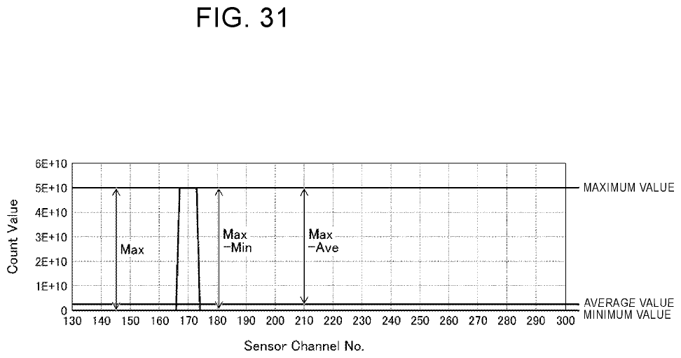

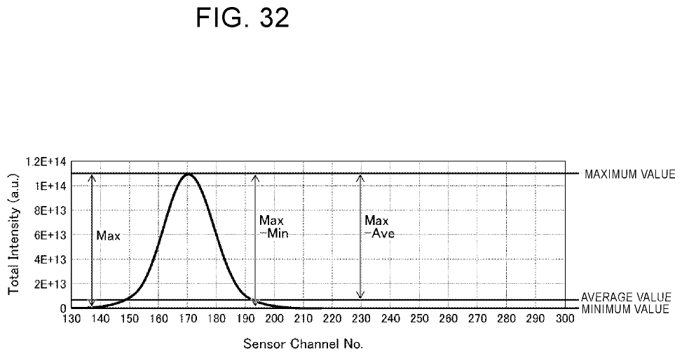

Integration of the count or integration of the light amount as shown in the first embodiment or the second embodiment is performed only for the sensor channels in this range, and similar threshold determination is performed using the maximum value, the difference between the maximum value and the minimum value, or the difference between the maximum value and the average value thereof (see FIGS. 31 and 32)

Integration of the count or the light amount may be performed not for all pulses but for every certain number of pulses. Integration of the count or the light amount may be performed not for the fringe waveform obtained by 1 pulse but for the fringe waveform obtained by integration of a certain number of pulses. Integration or the count or the light amount may be performed on the fringe waveform after subtracting the average value of the background noise calculated in advance.

FIG. 31 shows an example of the count values when 50 billion pulse is reached. FIG. 32 shows an example of the light amount integration values when 50 billion pulses is reached.

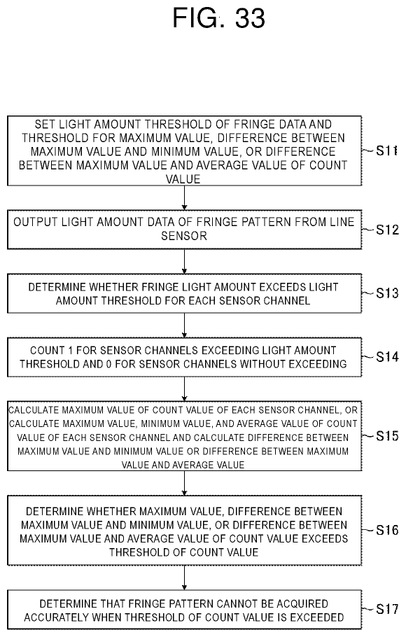

FIG. 33 is a flowchart showing an example of a process of counting the number of times the fringe light amount exceeds the light amount threshold Th1 for each sensor channel to determine the deterioration state of the line sensor 52.

In step S11, the sensor data management unit 160 sets the light amount threshold Th1 of the fringe data and the threshold Th2 for the maximum value, the difference between the maximum value and the minimum value, or the difference between the maximum value and the average value of the count value.

In step S12, the light amount data of the fringe pattern is output from the line sensor 52, and the sensor data management unit 160 acquires the light amount data output from the line sensor 52.

In step S13, the sensor data management unit 160 determines whether or not the fringe light amount exceeds the light amount threshold Th1 for each sensor channel.

In step S14, the sensor data management unit 160 counts “1” for the sensor channels with the fringe light amount exceeding the light amount threshold Th1, and “0” for the sensor channels without exceeding, and integrates the values.

In step S15, the sensor data management unit 160 calculates the maximum value of the count value of each sensor channel. Alternatively, the maximum value, the minimum value, and the average value of the count value of each sensor channel are calculated, and the difference between the maximum value and the minimum value or the difference between the maximum value and the average value is calculated.

In step S16, the sensor data management unit 160 determines whether or not the maximum value, the difference between the maximum value and the minimum value, or the difference between the maximum value and the average value of the count value exceeds the threshold Th2 of the count value.

In step S17, the sensor data management unit 160 determines that the fringe pattern cannot be acquired accurately when the threshold Th2 of the count value is exceeded.

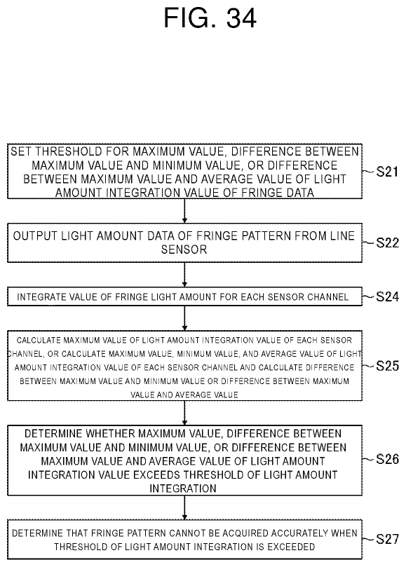

FIG. 34 is a flowchart showing an example of a process of integrating the fringe light amounts for each sensor channel to determine the deterioration state of the line sensor 52.

In step S21, the sensor data management unit 160 sets the threshold Th3 for the maximum value, the difference between the maximum value and the minimum value, or the difference between the maximum value and the average value of the light amount integration value of the fringe data.

In step S22, the light amount data of the fringe pattern is output from the line sensor 52, and the sensor data management unit 160 acquires the light amount data output from the line sensor 52.

In step S24, the sensor data management unit 160 integrates the fringe light amounts for each sensor channel.

In step S25, the sensor data management unit 160 calculates the maximum value of the light amount integration value of each sensor channel. Alternatively, the maximum value, the minimum value, and the average value of the light amount integration value of each sensor channel are calculated, and the difference between the maximum value and the minimum value or the difference between the maximum value and the average value is calculated.

In step S26, the sensor data management unit 160 determines whether or not the maximum value, the difference between the maximum value and the minimum value, or the difference between the maximum value and the average value of the light amount integration value exceeds the threshold Th3 of the light amount integration.

In step S27, the sensor data management unit 160 determines that the fringe pattern cannot be acquired accurately when the threshold Th3 of the light amount integration is exceeded.

### 8.3 Effect

According to the fourth embodiment, the deterioration state of the line sensor can be grasped more simply than in the first and second embodiments. Further, according to the fourth embodiment, the deterioration state of the line sensor can be grasped more accurately than in the third embodiment.

### 9. FIFTH EMBODIMENT

### 9.1 Configuration

The configuration of a fifth embodiment may be similar to that of the first embodiment shown in FIG. 12.

### 9.2 Operation

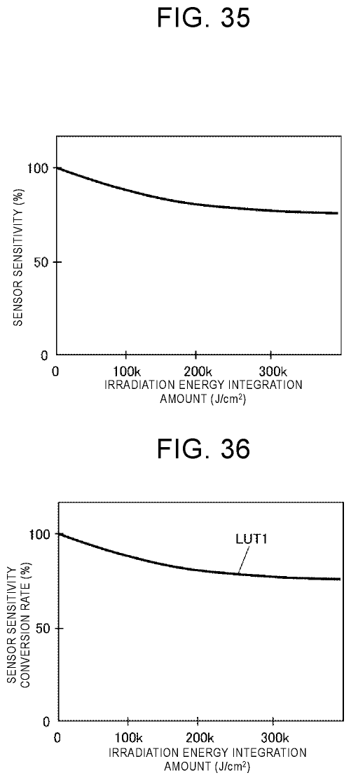

In the fifth embodiment, a process of correcting the deterioration amount that depends on the integration amount of ultraviolet irradiation energy is added to the calculation of the light amount integration value in the second embodiment. The amount of decrease in the sensitivity of the line sensors 52, 53 varies depending on the integration amount of ultraviolet irradiation energy (J/cm²). FIG. 35 is a graph showing an example of a sensor deterioration characteristic showing the relationship between an irradiation energy integration amount and a decrease in sensor sensitivity. The horizontal axis represents the irradiation energy integration amount, and the vertical axis represents the sensor sensitivity (%). For example, as shown in FIG. 35, the amount of deterioration (the amount of decrease in sensitivity) may slow down with an increase in the irradiation energy integration amount. This characteristic depends on the structure and material of the sensor.

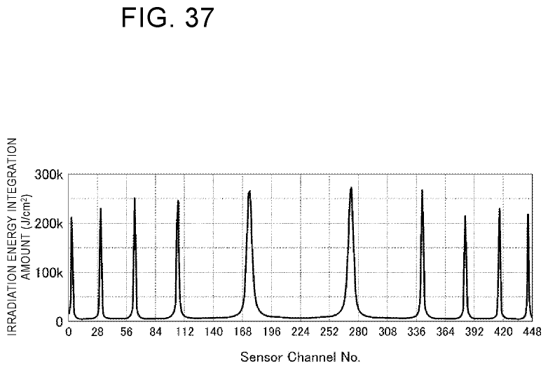

Therefore, in the fifth embodiment, a look-up table (LUT) reflecting the sensor deterioration characteristic is prepared in advance (see FIG. 36) so that the irradiation energy integration amount can be converted into the sensitivity of the sensor.

FIG. 36 is a graph showing an example of LUT1 representing the relationship between the irradiation energy integration amount and the sensor sensitivity conversion amount. The horizontal axis represents the irradiation energy integration amount (J/cm²), and the vertical axis represents the sensor sensitivity conversion rate (%). LUT1 shown in FIG. 36 is LUT reflecting the sensor deterioration characteristic shown in FIG. 35. The sensor data management unit 160 stores LUT1 as shown in FIG. 36, obtains the irradiation energy integration amount from the light amount integration value for each sensor channel, and estimates the sensitivity decreasing amount for each sensor channel using LUT1.

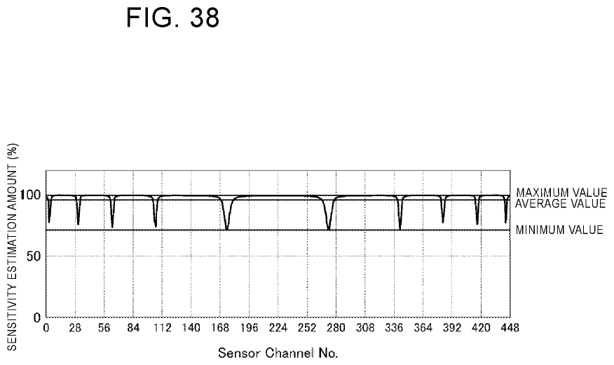

FIG. 37 is a graph obtained by converting the vertical axis of the graph of FIG. 26 into the irradiation energy integration amount. For example, when the fringe light amount integration value for each sensor channel of the line sensor 52 shown in FIG. 26 having 448 sensor channels is converted into the scale of the irradiation energy integration amount (J/cm²), a graph as shown in FIG. 37 is obtained. By performing LUT conversion using LUT1 shown in FIG. 36, sensitivity conversion values for each sensor channel as shown in FIG. 38 are obtained. LUT conversion to which LUT1 is applied is an example of the “nonlinear conversion” in the present disclosure.

The vertical axis before LUT conversion (FIG. 37) is an approximate irradiation energy integration amount (J/cm²) for each sensor channel, and the vertical axis after LUT conversion (FIG. 38) is a sensitivity estimation amount (%) for each sensor channel based on the sensor deterioration characteristic.

In the fifth embodiment, when the vertical axis of FIG. 26 is converted into the scale of the irradiation energy integration amount (J/cm²), the light amount integration amount (total intensity) of 4.0E+13 (a.u.) is simply set as the irradiation energy integration amount 100 (kJ/cm²). The notation “E+13” represents “10 to the 13th power.”

The sensor deterioration characteristic as shown in FIG. 35 or LUT1 as shown in FIG. 36 can be obtained by irradiating the actual line sensor with light of uniform and constant energy (the same wavelength as the target laser), and recording the channel average of the output value of the line sensor for each irradiation energy integration amount.

In the fifth embodiment, similarly to the first to fourth embodiments, in the deterioration determination of the sensor, the threshold determination may be performed by calculating the minimum value, the difference between the maximum value and the minimum value, or the difference between the minimum value and the average value of the sensitivity estimation amount. The threshold used for the threshold determination in the fifth embodiment is an example of the “third threshold” in the present disclosure. The sensitivity estimation amount calculated in the fifth embodiment is an evaluation index indicating that the deterioration of the sensor is progressing as the value thereof is smaller, and is an example of the “evaluation value” in the present disclosure.

### 9.3 Effect

According to the fifth embodiment, since the sensitivity decrease amount of the sensor can be estimated with higher accuracy, the accuracy of the deterioration determination is further improved.

### 10. SIXTH EMBODIMENT

### 10.1 Configuration

The configuration of a sixth embodiment may be similar to that of the first embodiment shown in FIG. 12.

### 10.2 Operation

In the sixth embodiment, a process of correcting the deterioration amount that depends on the integration amount of ultraviolet irradiation energy is added to the calculation of the sensitivity estimation amount in the fifth embodiment. Regarding the operation of the sixth embodiment, differences from that of the fifth embodiment will be described.

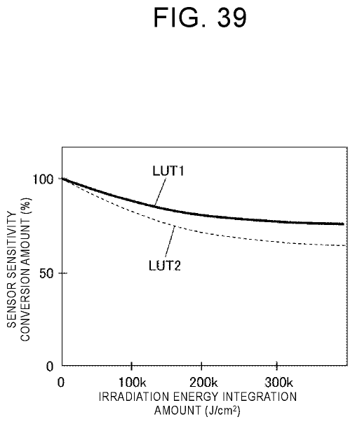

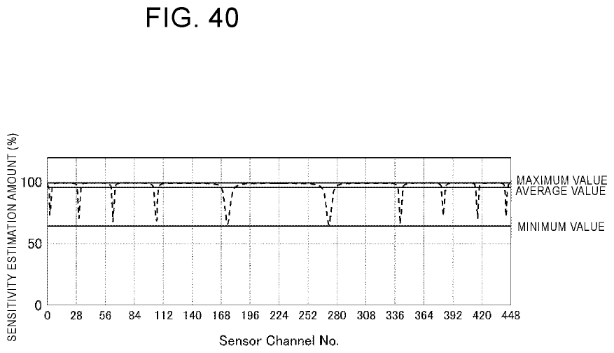

In the description of the fifth embodiment, the reason why the vertical axis of the graph of FIG. 37 is the approximate irradiation energy integration amount (J/cm²) for each sensor channel is that the data of FIG. 37 is not accurate integration of the actual irradiation energy, but integration of the signal value for each sensor channel output from the line sensor 52 at the time of irradiation. In a strict manner, since the sensor deteriorates each time light is irradiated, and the output (sensitivity) gradually decreases, the larger the light amount integration value of a channel is, the larger the actual irradiation energy integration amount of the channel is. Therefore, in order to further correct this effect, by performing conversion using LUT2 as shown by the broken line in FIG. 39 (see FIG. 40), it is possible to further improve the estimation accuracy of the deterioration amount of the sensor.

A curve indicated by a broken line in FIG. 39 is an example of LUT2 as a conversion table in which the decrease in sensitivity of the sensor due to the accumulation of the light irradiation is corrected. The curve indicated by a solid line is LUT1 described in FIG. 36, and is a conversion table in which the decrease in sensitivity of the sensor due to the accumulation of the light irradiation is not corrected.

FIG. 40 is a graph showing the sensitivity estimation amount for each sensor channel obtained by converting the data of FIG. 37 using LUT2 of FIG. 39. By calculating the minimum value, the difference between the maximum value and the minimum value, or the difference between the minimum value and the average value of the sensitivity estimation amount obtained in this way and performing the threshold determination, it is possible to accurately determine the deterioration state of the line sensor.

### 10.3 Effect

According to the sixth embodiment, since the sensitivity decrease amount of the sensor can be estimated with higher accuracy, the accuracy of the deterioration determination is further improved than in the fifth embodiment.

### 11. OTHER EXAMPLES OF LASER DEVICE

The laser oscillator including the chamber 20, the output coupling mirror 30, and the LNM 32 shown in FIG. 12 is an example of the “laser oscillator” in the present disclosure. The line narrowing gas laser device is exemplified in the first to sixth embodiments, but the laser oscillator is not limited to the gas laser device, and may be a solid-state laser device including a semiconductor laser. Further, the laser device may include a laser amplifier.

### 12. COMPUTER READABLE MEDIUM IN WHICH PROGRAM IS RECORDED

A program including instructions for causing a processor to function as the sensor data management unit 160 described in each of the above-described embodiments may be recorded on an optical disk, a magnetic disk, or another non-transitory computer readable medium (tangible non-transitory information storage medium), and the program may be provided through the computer readable medium. Further, the program recorded on the computer readable medium is incorporated in the computer, and a processor executes the instructions of the program, whereby the function of the sensor data management unit 160 can be realized by the computer.

### 13. ELECTRONIC DEVICE MANUFACTURING METHOD

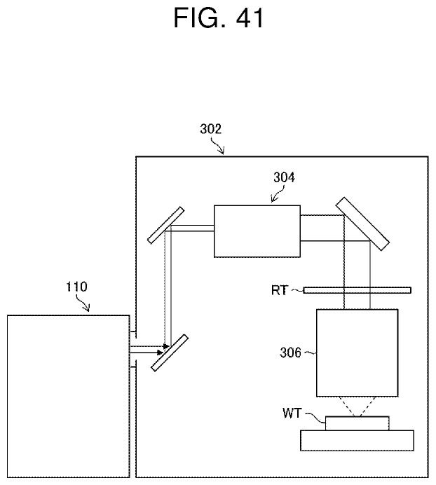

FIG. 41 schematically shows a configuration example of the exposure apparatus 302. An electronic device manufacturing method is performed by a system including the laser device 110 and the exposure apparatus 302. The pulse laser light output from the laser device 110 is input to the exposure apparatus 302 and used as exposure light.

The exposure apparatus 302 includes an illumination optical system 304 and a projection optical system 306. The illumination optical system 304 illuminates a reticle pattern of a reticle (not shown) arranged on a reticle stage RT with laser light incident from the laser device 110. The projection optical system 306 causes the laser light transmitted through the reticle to be imaged as being reduced and projected on a workpiece (not shown) arranged on a workpiece table WT. The workpiece is a photosensitive substrate such as a semiconductor wafer on which photoresist is applied.

The exposure apparatus 302 synchronously translates the reticle stage RT and the workpiece table WT to expose the workpiece to the laser light reflecting the reticle pattern. After the reticle pattern is transferred onto the semiconductor wafer by the exposure process described above, a semiconductor device can be manufactured through a plurality of processes. The semiconductor device is an example of the “electronic device” in the present disclosure.

### 14. OTHERS

In each of the above-described embodiments, an example in which the deterioration evaluation of the line sensors 52, 53 used in the monitor module 40 is performed has been described, but the line sensor to be evaluated is not limited to this example, and may be a line sensor applied to a detection unit other than the monitor module 40. The technique of the present disclosure is widely applicable as a technique for evaluating local deterioration of a line sensor used for detection of interference fringes of pulse laser light.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A deterioration evaluation method of a line sensor, comprising:
detecting an interference fringe of pulse laser light using the line sensor;
calculating, based on a signal value obtained from each of a plurality of sensor channels included in a sensor channel range being at least a part of the line sensor in accordance with light intensity of the interference fringe, an evaluation value which is an index of deterioration for each of the sensor channels or each group of the sensor channels, and storing the evaluation value in a storage device; and
determining a deterioration state of the line sensor based on the evaluation value.

2. The deterioration evaluation method of a line sensor according to claim 1,
wherein the evaluation value is a count value obtained by counting a number of times the signal value obtained from the sensor channel exceeds a first threshold.

3. The deterioration evaluation method of a line sensor according to claim 2,
wherein the count value is a value obtained by dividing an integration value of the counted number of times by a first constant.

4. The deterioration evaluation method of a line sensor according to claim 1,
wherein the evaluation value is a light amount integration value obtained by integrating the signal value or a value calculated by performing non-linear conversion on the light amount integration value.

5. The deterioration evaluation method of a line sensor according to claim 4,
wherein the light amount integration value is obtained by dividing an integration value of the signal value by a second constant.

6. The deterioration evaluation method of a line sensor according to claim 4,
wherein the light amount integration value is obtained by integrating a value obtained by subtracting a third constant from the signal value.

7. The deterioration evaluation method of a line sensor according to claim 4,
wherein the non-linear conversion is conversion reflecting a sensor deterioration characteristic indicating relationship between an irradiation energy integration amount of the pulse laser light and a decrease in sensor sensitivity.

8. The deterioration evaluation method of a line sensor according to claim 1,
further comprising calculating a fringe order from a light intensity distribution of the interference fringes detected by the line sensor,
wherein MavEx being the fringe order at a position with a distance r from a center of the interference fringes in a concentric shape is calculated by the following equation:
MavEx=r²/(rₘ₂²−rₘ₁²)
where rₘ₁ is a radius of an inner first interference fringe of the interference fringes and rₘ₂ is a radius of an inner second interference fringe thereof, and
the evaluation value is a count value obtained by grouping a range of the fringe order as the sensor channel range into a plurality of sections and counting a value of the fringe order for each fringe order group.

9. The deterioration evaluation method of a line sensor according to claim 1,
wherein determination of the deterioration state is performed by comparing the evaluation value with a second threshold.

10. The deterioration evaluation method of a line sensor according to claim 1,
further comprising obtaining a maximum value of the evaluation value,
wherein, when the maximum value of the evaluation value exceeds a second threshold, the line sensor is determined to have a fear of being incapable of obtaining an accurate interference fringe.

11. The deterioration evaluation method of a line sensor according to claim 1,
further comprising obtaining at least one of a maximum value, a minimum value, and an average value of the evaluation value.

12. The deterioration evaluation method of a line sensor according to claim 1,
further comprising obtaining a maximum value and a minimum value of the evaluation value,
wherein, when a difference between the maximum value and the minimum value of the evaluation value exceeds a second threshold, the line sensor is determined to have a fear of being incapable of obtaining an accurate interference fringe.

13. The deterioration evaluation method of a line sensor according to claim 1,
further comprising obtaining a maximum value and an average value of the evaluation value,
wherein, when a difference between the maximum value and the average value of the evaluation value exceeds a second threshold, the line sensor is determined to have a fear of being incapable of obtaining an accurate interference fringe.

14. The deterioration evaluation method of a line sensor according to claim 11,
wherein the evaluation value is an index indicating that deterioration is progressing as the evaluation value is smaller, and
determination of the deterioration state is performed by comparing the minimum value, a difference between the maximum value and the minimum value, or a difference between the average value and the minimum value with a third threshold.

15. The deterioration evaluation method of a line sensor according to claim 1,
wherein a processor executes a process of calculating the evaluation value from data of the signal value for each of the sensor channels, a process of storing the evaluation value in the storage device, and a process of outputting a determination result as determining a deterioration state of the line sensor based on the evaluation value.

16. The deterioration evaluation method of a line sensor according to claim 15,
wherein the process of outputting the determination result includes at least one of a process of displaying the determination result on a display device, a process of performing notification based on the determination result, and a process of recording the determination result in a log.

17. A spectrum measurement device comprising:
an optical system configured to generate an interference fringe by causing pulse laser light to be incident thereon;
a line sensor configured to detect the interference fringe; and
a processor configured to process information obtained from the line sensor,
the processor being configured to calculate, based on a signal value obtained from each of a plurality of sensor channels included in a sensor channel range being at least a part of the line sensor in accordance with light intensity of the interference fringe, an evaluation value which is an index of deterioration for each of the sensor channels or each group of the sensor channels, store the evaluation value in a storage device, and determine a deterioration state of the line sensor based on the evaluation value.

18. The spectrum measurement device according to claim 17,
wherein the optical system includes an etalon or a grating, and
the processor measures at least one of a wavelength and a spectral line width of the pulse laser light based on the information obtained from the line sensor.

19. A laser device comprising:
the spectrum measurement device according to claim 17; and
a laser oscillator configured to output the pulse laser light.

20. A computer readable medium, being a non-transitory computer readable medium, in which a program is recorded, the program causing a processor to execute a process of acquiring a signal output from a line sensor which detects an interference fringe of pulse laser light, a process of calculating, based on a signal value obtained from each of a plurality of sensor channels included in a sensor channel range being at least a part of the line sensor in accordance with light intensity of the interference fringe, an evaluation value which is an index of deterioration for each of the sensor channels or each group of the sensor channels and storing the evaluation value in a storage device, and a process of determining a deterioration state of the line sensor based on the evaluation value.
